(19) United States
(12) Patent Application Publication
(10) Pub. No.: US 2026/0047027 A1
(43) Pub. Date: Feb. 12, 2026

(54) Cable Management System For Server Information Handling System Rack

(71) Applicant: Dell Products L.P., Round Rock, TX (US)

(72) Inventors: Lawrence Ying-Hsi Lin, ZhongZheng DIstrict (TW); Xingcai Pan, Shanghai (CN); Chuan Chieh Tseng, Yonghe District (TW)

(21) Appl. No.: 18/797,651

(22) Filed: Aug. 8, 2024

(51) Int. Cl. H05K 7/14

(52) U.S. Cl. CPC H05K 7/1491; H05K 7/1489

(57) ABSTRACT

A cable management system for an information handling system server rack. The cable management system includes a rail mounting component, the rail mounting component being configured to physically attach to the information handling system server rack and a cable management component, the cable management component being physically attached to the rail mounting component, the cable management component extending across a rear of the information handling system server rack.

### BACKGROUND OF THE INVENTION

### FIELD OF THE INVENTION

The present invention relates to information handling systems. More specifically, embodiments of the invention relate to server type information handling systems within information technology (IT) environments.

### DESCRIPTION OF THE RELATED ART

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing an information handling system server rack with a cable management system.

In one embodiment, the invention relates to a cable management system for an information handling system server rack, comprising: a rail mounting component, the rail mounting component being configured to physically attach to the information handling system server rack; and, a cable management component, the cable management component being physically attached to the rail mounting component, the cable management component extending across a rear of the information handling system server rack.

In another embodiment, the invention relates to an information handling system server rack comprising: a rear side panel; and, a cable management system, the cable management system comprising a rail mounting component, the rail mounting component being configured to physically attach to the rear side panel of the information handling system server rack; and, a cable management component, the cable management component being physically attached to the rail mounting component, the cable management component extending across a rear of the information handling system server rack.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIGS. 3A, 3B and 3C, generally referred to as FIG. 3, show a rack front view, a rack side view, and a rack side view with an information handling system in an accessible position.

FIGS. 4A and 4B, generally referred to as FIG. 4, shows generalized perspective views of an example rack server type information handling system.

FIGS. 5A and 5B, generally referred to as FIG. 5, show generalized side views of a server rack and a cable management system.

FIGS. 6A and 6B, generally referred to as FIG. 6, show perspective views of a cable management system.

FIGS. 7A and 7B, generally referred to as FIG. 7, show side views of rack mounting portion of a cable management system.

FIGS. 8A and 8B, generally referred to as FIG. 8, show perspective views of a rack mounting fastener of a cable management system.

FIGS. 9A, 9B, 9C, 9D, 9E, 9F and 9G, generally referred to as FIG. 9, show a plurality of views of a cable management system.

### DETAILED DESCRIPTION

Various aspects of the present disclosure include an appreciation that it is known to install a cable management bar (CMB) on a rear side of a server information handling system chassis. Various aspects of the present disclosure include an appreciation that it is known to use a cable management bar to perform a cable management function.

Various aspects of the present disclosure include an appreciation that it is known to provide certain information handling system chassis with a rear side structure design which extends from a rear portion of the information handling system chassis. Various aspects of the present disclosure include an appreciation that such a rear side structure can interfere with installation of a cable management bar to the rear of the server information handling system chassis. Accordingly, various aspects of the present disclosure include an appreciation that it would be desirable to provide a cable management system that is adaptable to information handling systems having different rear chassis designs.

Various aspects of the present disclosure include an appreciation that rack depths conforming to certain rack standards can have a plurality of rack depths. For example, with an Enterprise Information Architecture (EIA) rack standard, the rack depths can vary from substantially 24” to 29.” Various aspects of the present disclosure include an appreciation that different rack depths can often result in a need for different cable management designs. Accordingly, various aspects of the present disclosure include an appreciation that it would be desirable to provide a cable management system that is adaptable to a plurality of rack depths.

A system and method are disclosed for providing a configurable cable management system. In certain embodiments, the configurable cable management system is adaptable to information handling systems having different rear chassis designs. In certain embodiments, the cable management system is adaptable to a plurality of rack depths.

In certain embodiments, the cable management system is configured to be installed to a server rack. In certain embodiments, the cable management system is configured to fit a plurality of different server information handling system chassis designs. In certain embodiments, the plurality of different server information handling system designs includes a rear side structure rear server chassis design. In certain embodiments, the cable management system is configured to fit a plurality of different rack dimensions. In certain embodiments, the plurality of different rack dimensions corresponds to a plurality of EIA rack dimensions.

In certain embodiments, the cable management system includes a one or more adjustable length mounting components. In certain embodiments, the one or more adjustable length mounting components enable the cable management system to fit a plurality of different EIA rack settings.

Such a cable management system advantageously leverages a single design across a plurality of server chassis designs, a plurality of server rack designs, or a combination thereof. Such a cable management system advantageously saves on tooling costs. Such a cable management system advantageously saves on stocking costs.

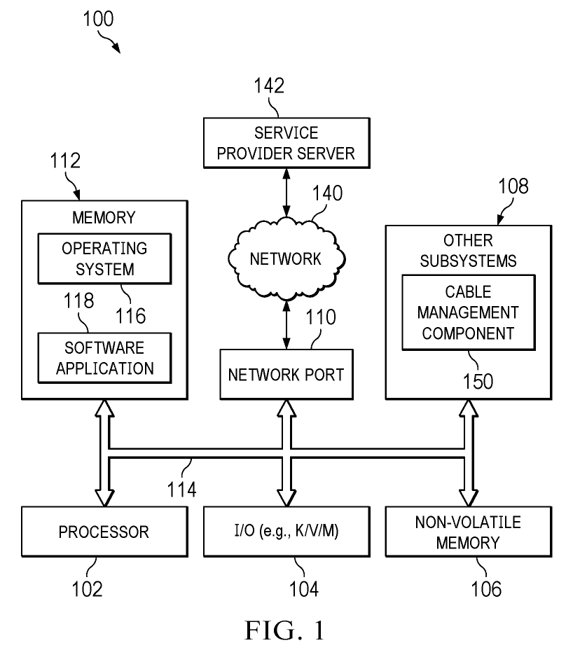

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

In certain embodiments, the information handling system 100 includes a cable management system 150. In certain embodiments, the cable management system 150 includes a configurable cable management system. In certain embodiments, the cable management system 150 is adaptable to information handling systems having different rear chassis designs. In certain embodiments, the cable management system 150 is adaptable to a plurality of rack depths.

In certain embodiments, the cable management system 150 is configured to be installed to a server rack. In certain embodiments, the cable management system 150 is configured to fit a plurality of different server information handling system chassis designs. In certain embodiments, the plurality of different server information handling system designs includes a rear side structure rear server chassis design. In certain embodiments, the cable management system 150 is configured to fit a plurality of different rack dimensions. In certain embodiments, the plurality of different rack dimensions corresponds to a plurality of EIA rack dimensions.

In certain embodiments, the cable management system 150 includes one or more adjustable length mounting components. In certain embodiments, the one or more adjustable length mounting components enable the cable management system to fit a plurality of different EIA rack settings.

Such a cable management system 150 advantageously leverages a single design across a plurality of server chassis designs, a plurality of server rack designs, or a combination thereof. Such a cable management system 150 advantageously saves on tooling costs. Such a cable management system 150 advantageously saves on stocking costs.

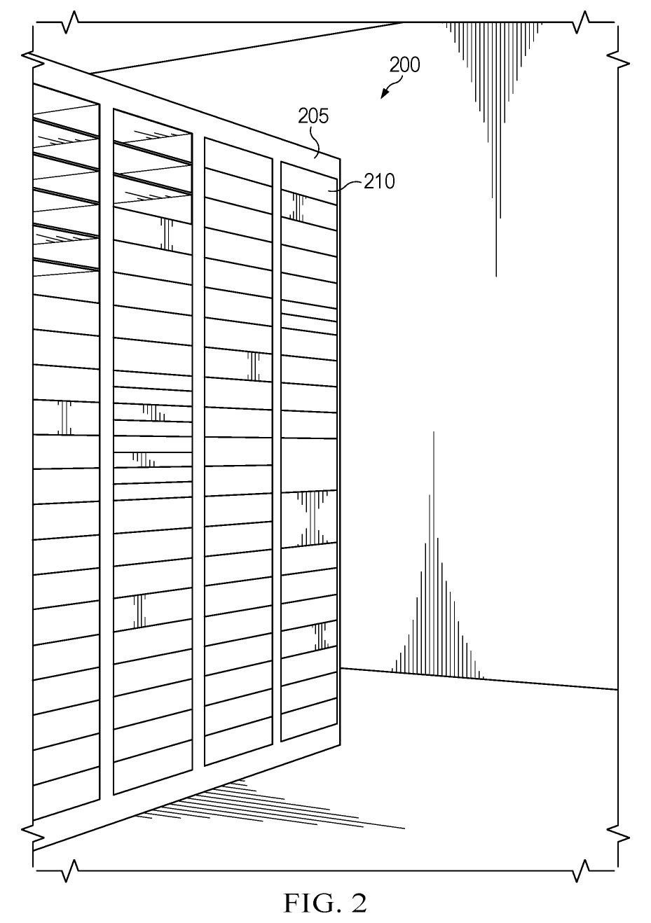

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/-20%) 1.75” high, a 2U rack unit is substantially (i.e., +/-20%) 3.5” high and a 4U rack height is substantially (i.e., +/-20%) 7.0” high. In certain embodiments, the plurality of service sizes includes open rack (OU) server sizes. As used herein, an open rack server size broadly refers to a standardized server system height conforming to an OpenRack standard.

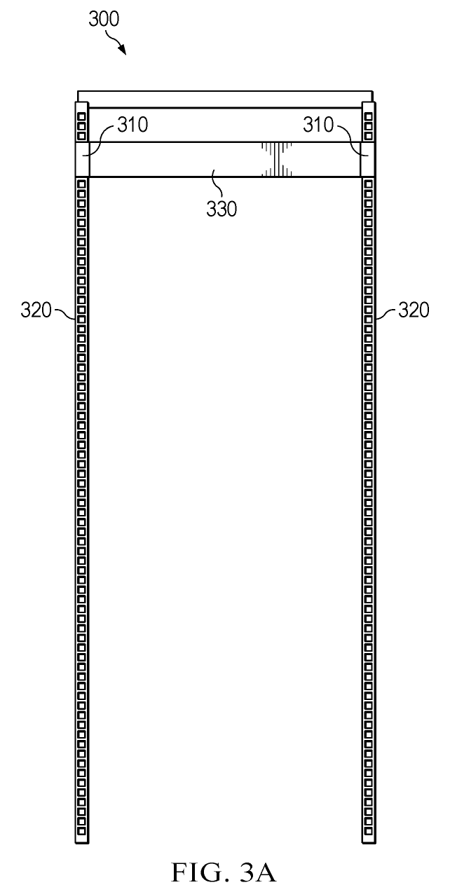

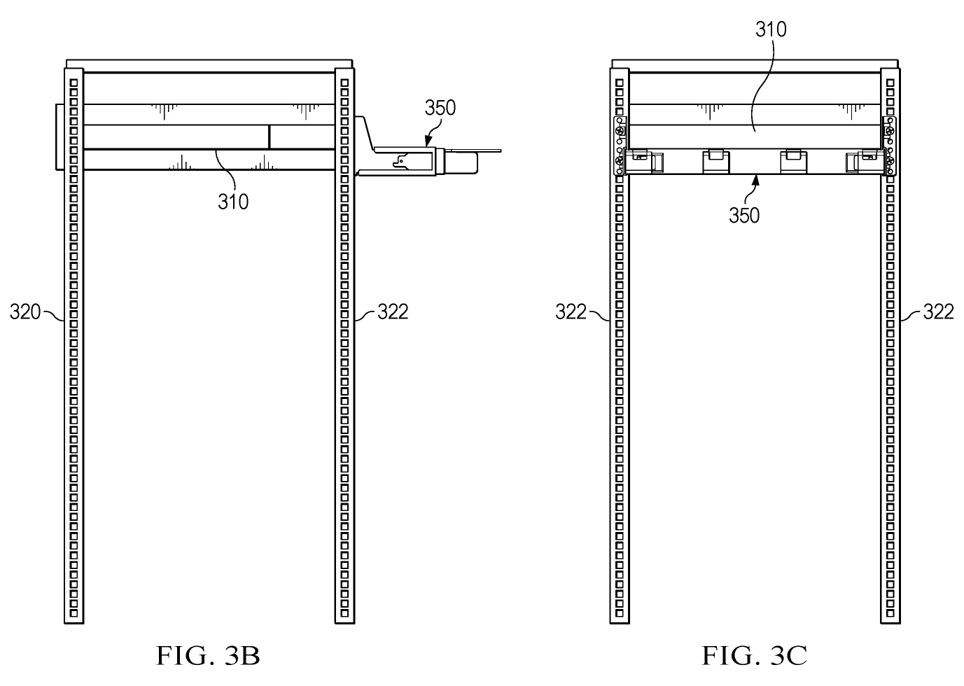

FIGS. 3A, 3B and 3C show a rack front view, a rack side view, and a rack rear view of a rack 300 in which an information handling system is mounted. A first server mounting component 310 is attached to one side of the rack and a second server mounting component 310 is attached to another side of the rack 300. In certain embodiments, the first server mounting component is attached to a first front side panel 320 and a first rear side panel 322 of the rack 300. In certain embodiments, the second server mounting component is attached to a second front side panel 320 and a second rear side panel 322 of the rack 300. In certain embodiments, the first server mounting component 320 is attached via the mounting apertures 330. In certain embodiments, the second server mounting component is attached via the mounting apertures 330.

In certain embodiments, the rack has a plurality of dimensions. In certain embodiments, the plurality of dimensions includes a width dimension, a depth dimension, a height dimension, or a combination thereof. In certain embodiments, the width dimension is defined by a distance from the first front side panel 320 and the second front side panel 320. In certain embodiments, the depth dimension of the rack is defined by a distance from a front side panel 320 and a rear side panel 322. In certain embodiments, the height dimension is defined by a distance from a bottom of a side panel 320 to a top of the side panel 320.

In certain embodiments, a rack includes a plurality of vertically arranged mounting components. In certain embodiments, some or all of the vertically arranged mounting components are adapted to mount respective rack server type information handling systems to the rack. In certain embodiments, the server mounting components are configured to correspond to particular heights including rack unit heights and open unit heights.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

In certain embodiments, the rack system 300 includes a cable management system 350. In certain embodiments, the cable management system 350 corresponds to cable management system 150. In certain embodiments, the cable management system 350 includes a configurable cable management system. In certain embodiments, the cable management system 350 is adaptable to information handling systems having different rear chassis designs. In certain embodiments, the cable management system 350 is adaptable to a plurality of rack depths.

In certain embodiments, the cable management system 350 is configured to be installed to a server rack. In certain embodiments, the cable management system 350 is configured to fit a plurality of different server information handling system chassis designs. In certain embodiments, the plurality of different server information handling system designs includes a rear side structure rear server chassis design. In certain embodiments, the cable management system 350 is configured to fit a plurality of different rack dimensions. In certain embodiments, the plurality of different rack dimensions corresponds to a plurality of EIA rack dimensions.

In certain embodiments, the cable management system 350 includes one or more adjustable mounting components. In certain embodiments, the one or more adjustable mounting components enable the cable management system to fit a plurality of different rack configurations. In certain embodiments, the one or more adjustable mounting components enable the cable management system to fit a plurality of different EIA rack configurations. In certain embodiments, the one or more adjustable mounting components enable a depth of the cable management system 350 to be adjusted.

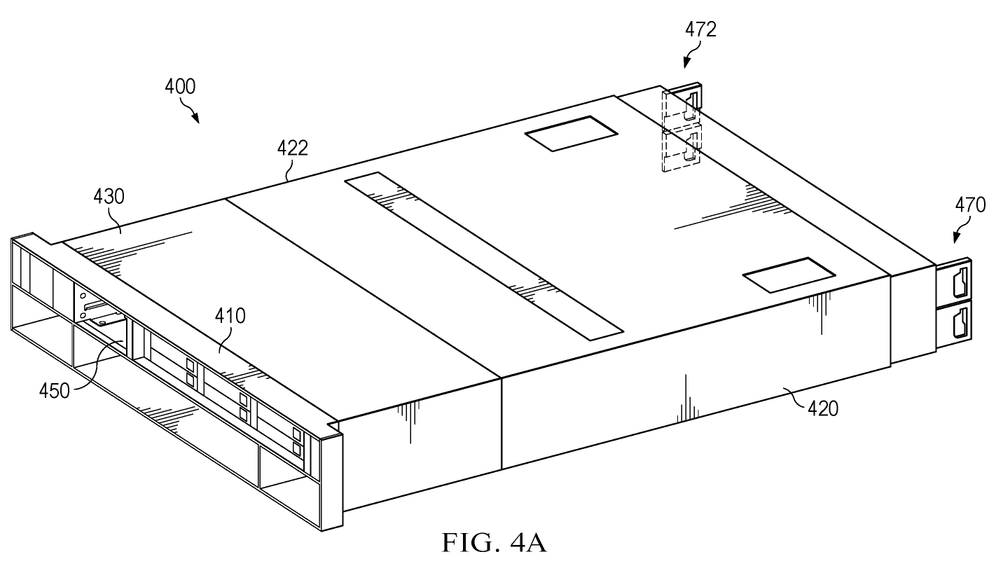

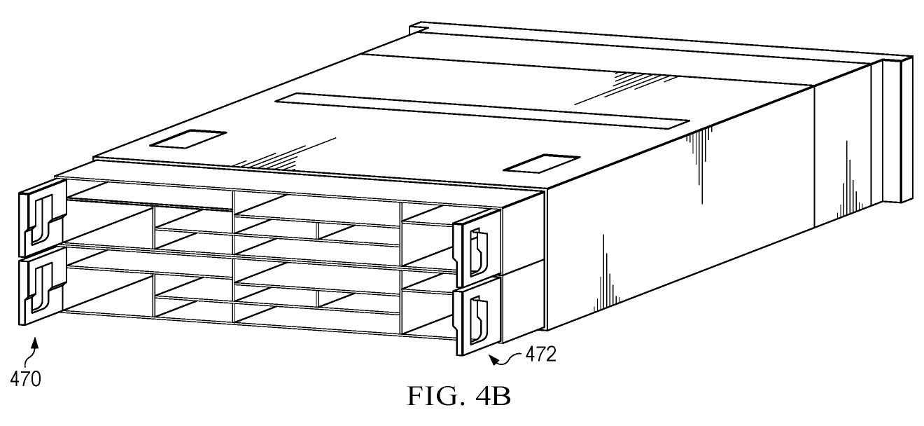

FIGS. 4A and 4B, generally referred to as FIG. 4, show generalized perspective views of an example rack server type information handling system 400. In certain embodiments, the rack server type information handling system 400 corresponds to information handling system 100.

In certain embodiments, the rack server type information handling system 400 includes a front portion 410, which is accessible when the rack server type information handing system 400 is mounted on a server rack. In certain embodiments, the side portions 420, 422 mount to the rack via respective server mounting components. In certain embodiments, the side portions mount to the rack via respective mechanical guiding features which are mechanically coupled to respective server mounting components. In certain embodiments, the rack server type information handling system can slide out from the rack via the respective mechanical guiding features. In certain embodiments, the rack type information handing system 400 includes a bay 450 via which components may be mounted to the rack type information handling system.

In certain embodiments, the rack server type information handing system 400 includes a rear portion 460. In certain embodiments, the rear portion 460 includes one or more rear side structures 470, 472. In certain embodiments, the one or more rear side structures extend rearwardly from respective sides of the information handling system chassis. In certain embodiments, the one or more rear side structures 470, 772 extend beyond the rear rails of the server rack. In certain embodiments, the one or more rear side structures 470, 472 include respective latch features.

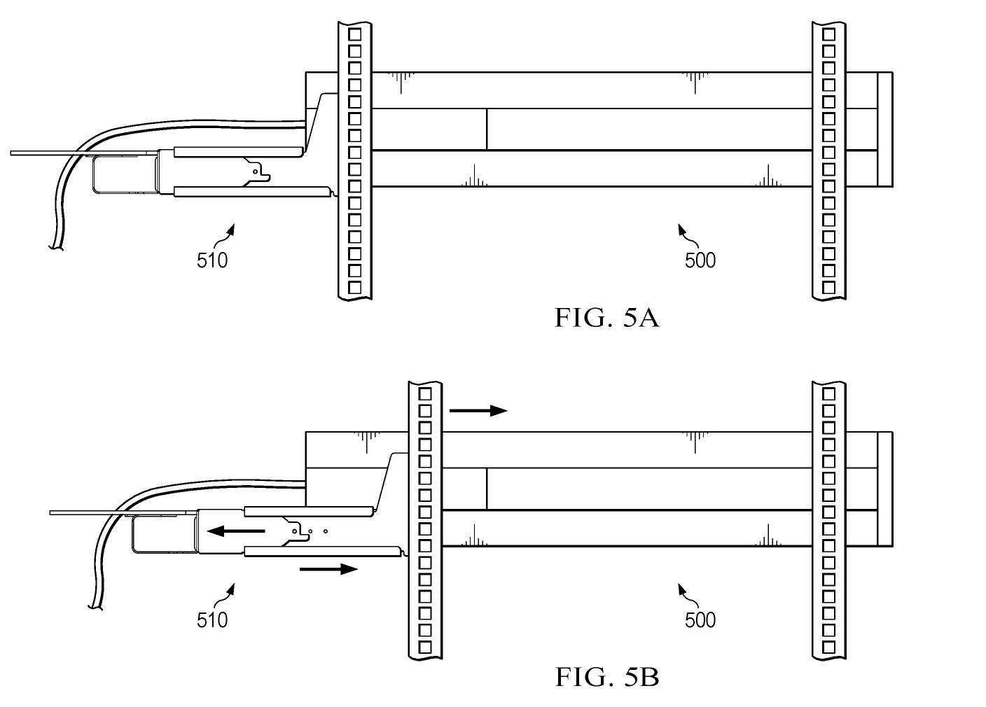

FIGS. 5A and 5B, generally referred to as FIG. 5, show generalized side views of a server rack 500 and a cable management system 510. More specifically, FIG. 5A shows a side view of a first type of server rack. FIG. 5B shows a side view of a second type of server rack. In certain embodiments, the first type of server rack has a first depth. In certain embodiments, the first depth is substantially 29.” In certain embodiments, the first type of server rack corresponds to a first type of EIA server rack. In certain embodiments, the first type of EIA server rack corresponds to a 29” deep EIA server rack. In certain embodiments, the second type of server rack has a second depth. In certain embodiments, the second depth is substantially 24.” In certain embodiments, the second type of server rack corresponds to a second type of EIA server rack. In certain embodiments, the second type of EIA server rack corresponds to a 24” deep EIA server rack.

In certain embodiments, the cable management system 510 is installed directly on one or more rails of the server rack 500. Because the cable management system 510 is installed directly on the rails of the server rack 500, the cable management system 510 can be installed on server racks of different depths. In certain embodiments, because the cable management system 510 is configurable, the cable management system 510 can be installed on server racks of different depths.

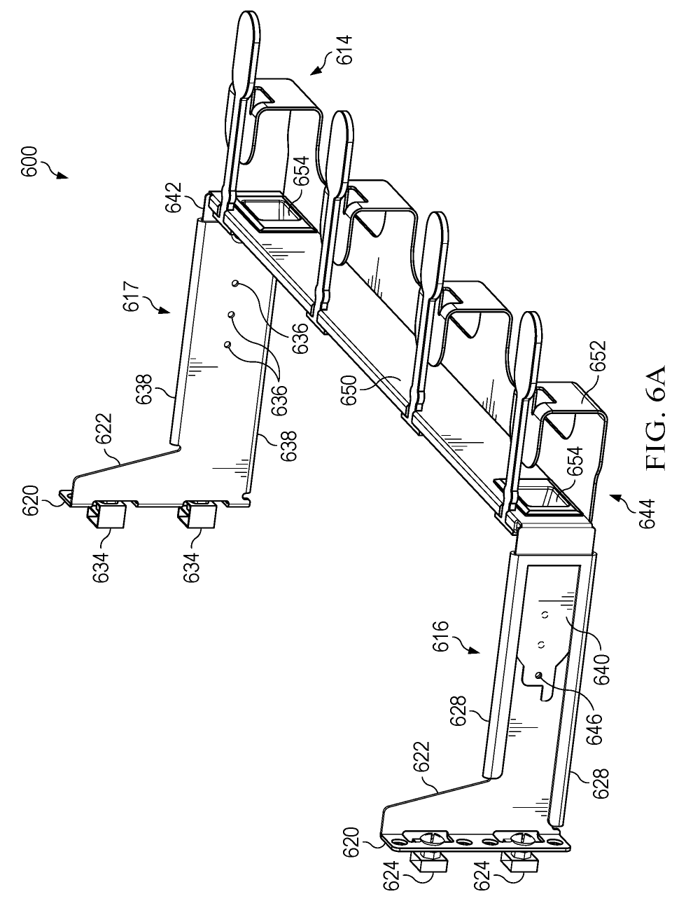

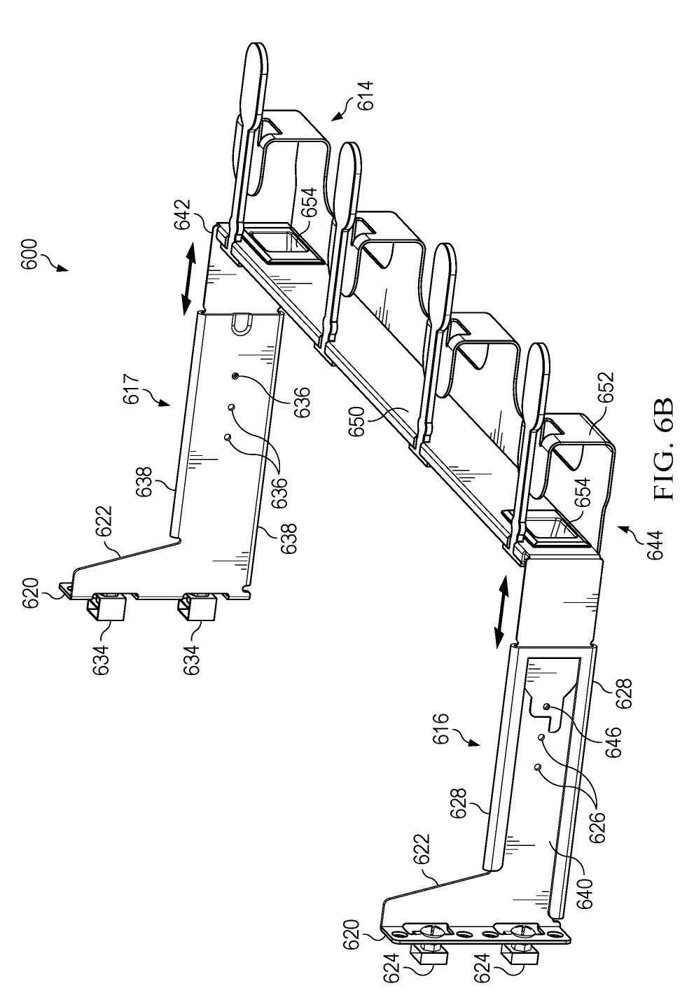

FIGS. 6A and 6B, generally referred to as FIG. 6, show perspective views of a cable management system 600. More specifically, FIG. 6A shows a perspective view of a cable management system 600 in a first configuration. FIG. 6B shows a perspective view of a cable management system 600 in a second configuration. In certain embodiments, the cable management system 600 corresponds to cable management system 150. In certain embodiments, the cable management system 600 is adaptable to information handling systems having different rear chassis designs. In certain embodiments, the cable management system 600 is adaptable to a plurality of rack depths.

In certain embodiments, the cable management system 600 includes a rail mounting component and a cable management component. In certain embodiments, the rail mounting component is configured to physically attach the cable management system to the information handling system server rack. In certain embodiments, the cable management component extends across a rear of the information handling system server rack.

In certain embodiments, the cable management system 600 is configured to be installed to a server rack. In certain embodiments, the cable management system 600 is configured to fit a plurality of different server information handling system chassis designs. In certain embodiments, the plurality of different server information handling system designs includes a rear side structure rear server chassis design. In certain embodiments, the cable management system 600 is configured to fit a plurality of different rack dimensions. In certain embodiments, the plurality of different rack dimensions corresponds to a plurality of EIA rack dimensions.

In certain embodiments, the cable management system 600 provides an adjustable cable management component mounting function. In certain embodiments, the adjustable cable management component mounting function enables the cable management system to fit a plurality of different rack configurations. In certain embodiments, the adjustable cable management component mounting function enables the cable management system to fit a plurality of different EIA rack configurations. In certain embodiments, the adjustable cable management component mounting function enables a depth of the cable management system 600 to be adjusted. In certain embodiments, the depth of the cable management system 600 is adjusted by adjusting a depth of the cable management component relative to the server rack.

In certain embodiments, the cable management system 600 includes a first rail mounting component 610, a second rail mounting component 612, a cable management component 614, or a combination thereof. In certain embodiments, the first rail mounting component 610 corresponds to a left side rail mounting component. In certain embodiments, the second rail mounting component 610 corresponds to a right side rail mounting component.

In certain embodiments, the first rail mounting component 610 includes a first rail mounting wall 620, a first cable management component mounting extension 622, or a combination thereof. In certain embodiments, the first rail mounting wall 620 extends substantially perpendicularly to the first cable management component mounting extension 622. In certain embodiments, the first rail mounting wall 620 and the first cable management component extension 622 are constructed from a single piece of material.

In certain embodiments, the first rail mounting wall 620 includes one or more rail mounting features 624. In certain embodiments, the one or more rail mounting features 624 are used to physically attach the first rail mounting component to a rail of a server rack. In certain embodiments, the first cable management component mounting extension 622 defines a plurality of cable management component mounting apertures 626. In certain embodiments, the plurality of cable management component apertures 626 extends horizontally across the first cable management mounting extension 622. In certain embodiments, the first cable management component mounting extension 622 includes a first plurality of guide rails 628.

In certain embodiments, the second rail mounting component 612 includes a second rail mounting wall 630, a second cable management component mounting extension 632, or a combination thereof. In certain embodiments, the second rail mounting wall 630 extends substantially perpendicularly to the second cable management component mounting extension 632. In certain embodiments, the second rail mounting wall 630 and the second cable management component mounting extension 632 are constructed from a single piece of material.

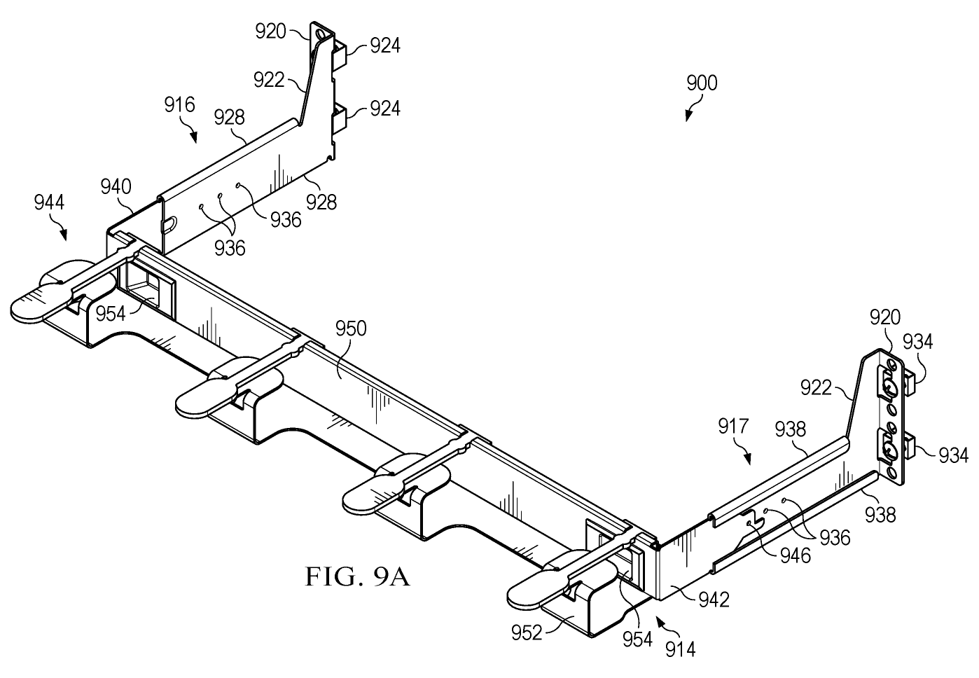

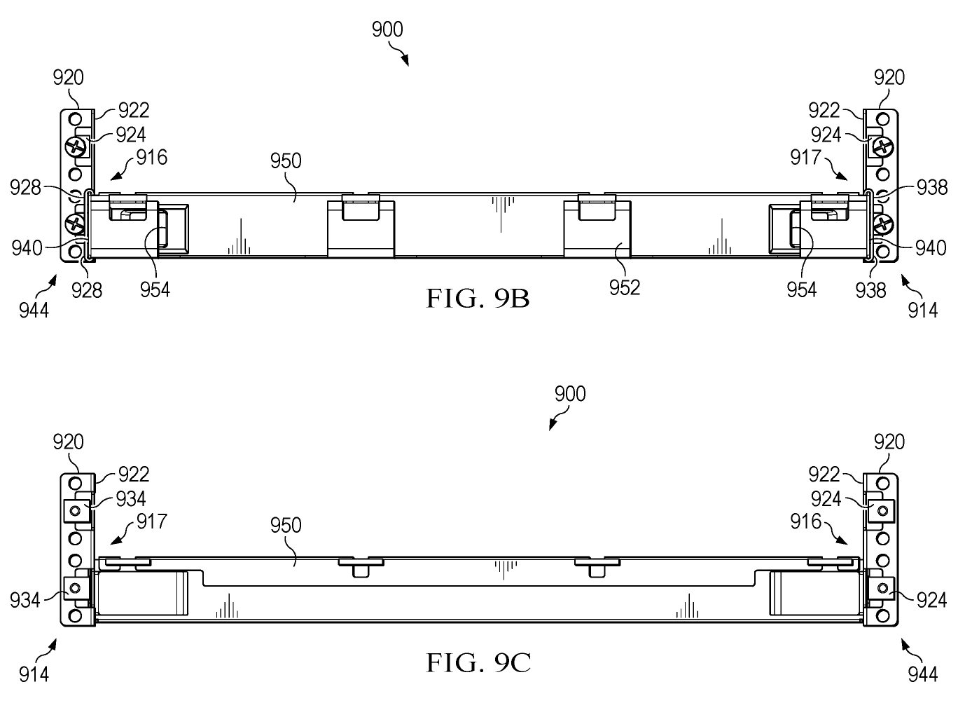

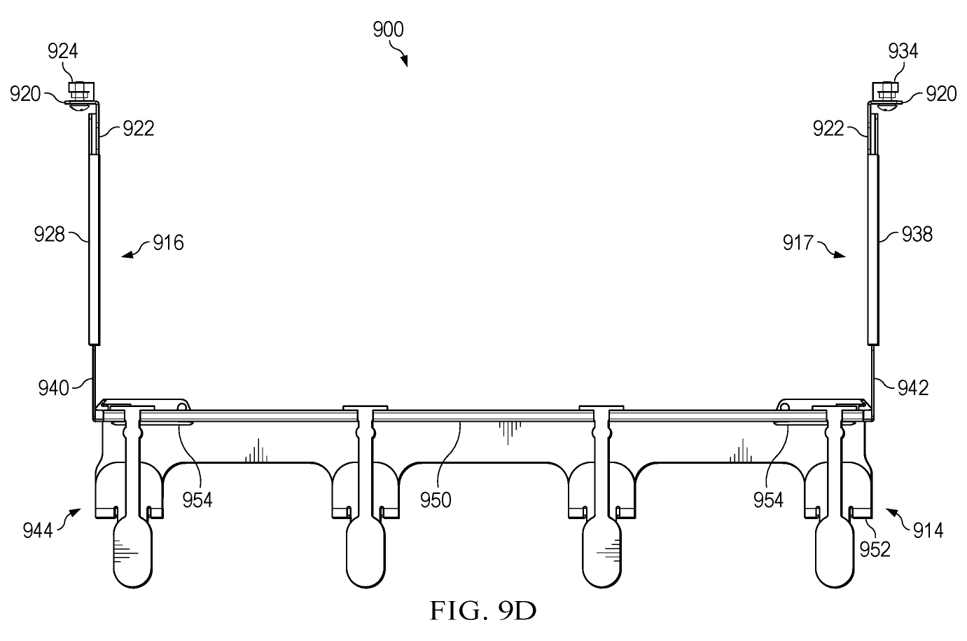

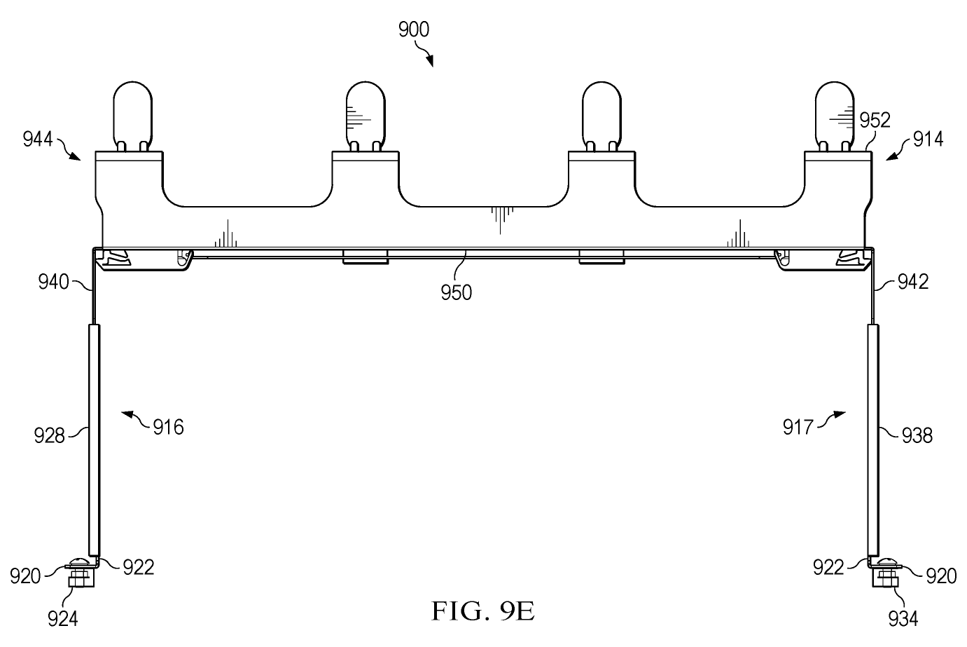

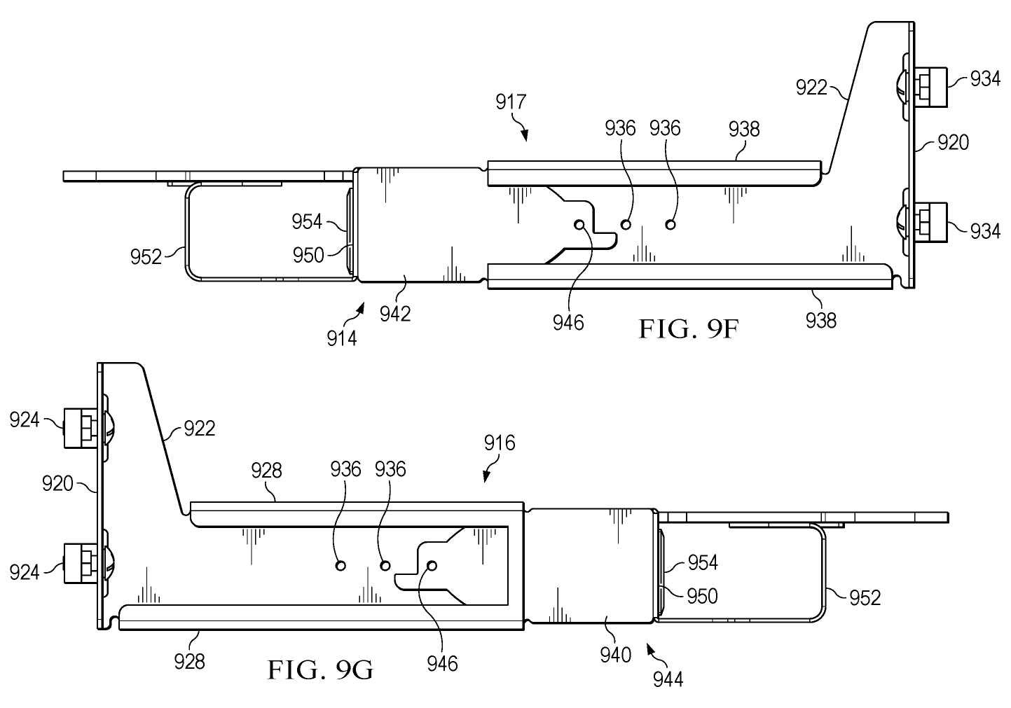

In certain embodiments, the second rail mounting wall 630 includes one or more rail mounting features 634. In certain embodiments, the one or more rail mounting features 634 are used to physically attach the second rail mounting component to a rail of a server rack. In certain embodiments, the second cable management component mounting extension 632 defines a plurality of cable management component mounting apertures 636. In certain embodiments, the plurality of cable management component apertures 636 extends horizontally across the second cable management mounting extension 632. In certain embodiments, the second cable management component mounting extension 632 includes a second plurality of guide rails 638 (see e.g., FIG. 9).

In certain embodiments, the cable management component 614 includes a first mounting extension 640, a second mounting extension 642, a cable management portion 644 or a combination thereof. In certain embodiments, the first mounting extension 640 extends substantially perpendicularly to the cable management portion 644. In certain embodiments, the second mounting extension 642 extends substantially perpendicularly to the cable management portion 644. In certain embodiments, the first mounting extension 640 defines a first mounting extension aperture 646. In certain embodiments, the second mounting extension 642 defines a second mounting extension aperture. In certain embodiments, the first mounting extension 640 mates with the first plurality of guide rails 628 of the first cable management component mounting extension 622. In certain embodiments, the second mounting extension 642 mates with the second plurality of guide rails 638 of the second cable management component mounting extension 632.

In certain embodiments, the cable management portion 644 includes a wall 650 and a plurality of cable management features 652 extending from the wall 650. In certain embodiments, the wall 650 defines one or more cable management apertures 654. In certain embodiments, the first mounting extension 640 extends substantially perpendicularly to wall 650 of the cable management portion 644. In certain embodiments, the second mounting extension 642 extends substantially perpendicularly to wall 650 of the cable management portion 644. In certain embodiments, the first mounting extension 640 the second mounting extension 642 and the wall 650 are integrated within a single piece of material.

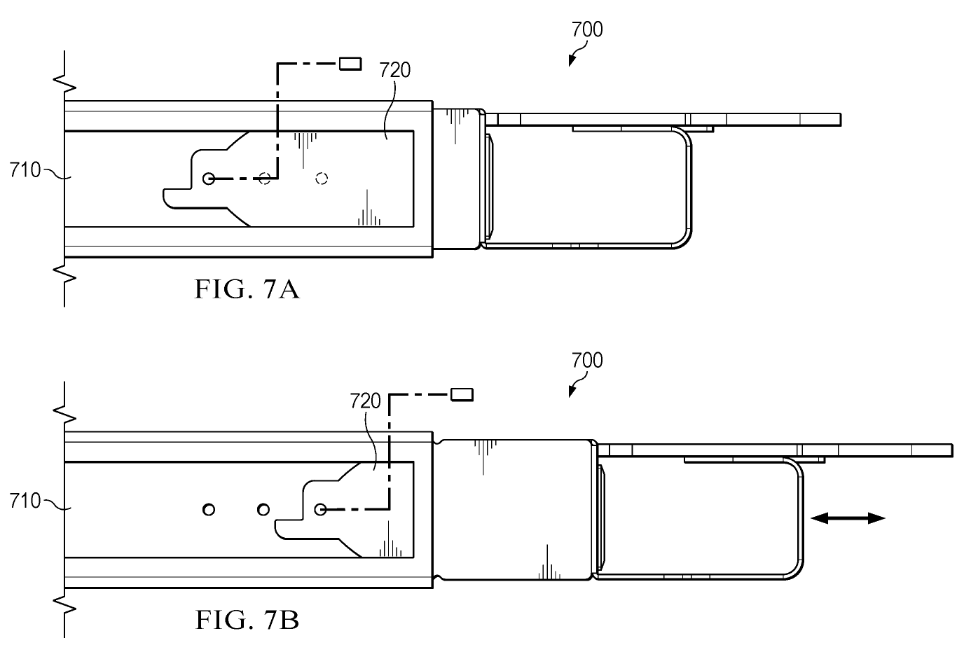

FIGS. 7A and 7B, generally referred to as FIG. 7, show side views of rack mounting portion of a cable management system. FIG. 7A shows a side view of a rack mounting portion 700 of a cable management system in a first configuration. FIG. 7B shows a side view of rack mounting portion 700 a cable management system in a second configuration. In certain embodiments, the rack mounting portion 700 of cable management system corresponds to a portion of cable management system 150.

In certain embodiments, the rack mounting portion 700 includes a rail mounting component 710, a mounting extension 720, or a combination thereof. In certain embodiments, the rail mounting component 710 corresponds to the first rail mounting component 610 or the second rail mounting component 612. In certain embodiments, the mounting extension 720 corresponds to the first mounting extension 640 or the second mounting extension 642.

In certain embodiments, the cable management system is adaptable to information handling systems having different rear chassis designs. In certain embodiments, the cable management system 600 is adaptable to a plurality of rack depths.

In certain embodiments, the rack mounting portion 700 of cable management system is configured to be installed directly to a rail of the server rack 500. Because the cable management system is installed directly on the rails of the server rack, the cable management system can be installed on server racks of different depths. In certain embodiments, because the cable management system is configurable, the cable management system can be installed on server racks of different depths.

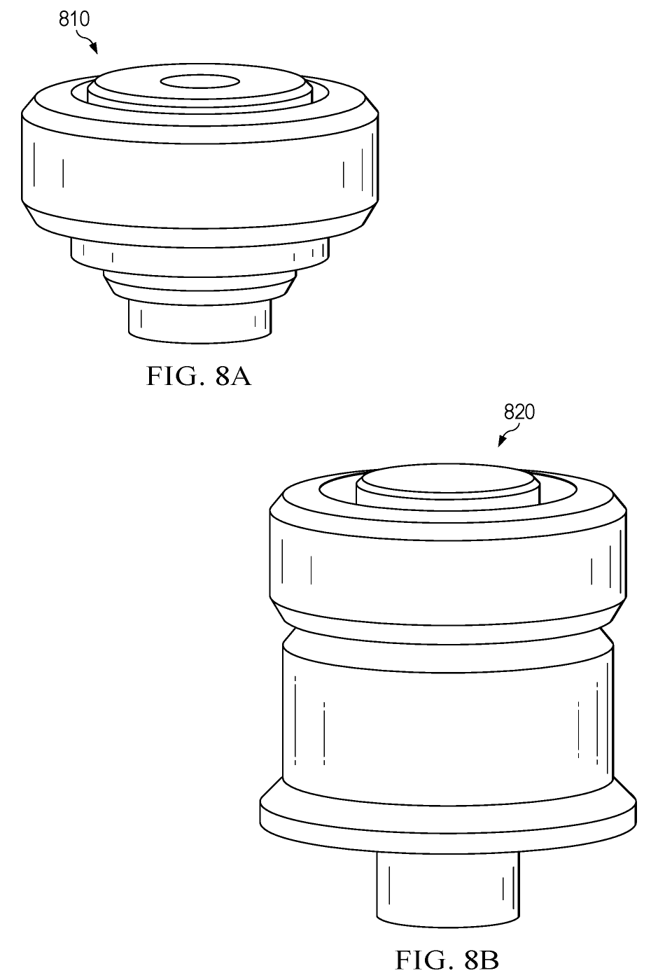

FIGS. 8A and 8B, generally referred to as FIG. 8, show perspective views of a mounting fastener of a cable management system. More specifically, FIG. 8A shows an example of a screw type fastener 810 of a cable management system. FIG. 8B shows an example of a plunger type fastener 820 of a cable management system. In various embodiments, the mounting fastener physically attaches the rail mounting component to a rail mounting extension. In certain embodiments, the mounting fastener is included as part of a rack mounting portion of a cable management system.

FIGS. 9A, 9B, 9C, 9D, 9E, 9F and 9G, generally referred to as FIG. 9, show a plurality of views of a cable management system 900. More specifically, FIG. 9A shows a perspective view of a cable management system 900. FIG. 9B shows a front view of a cable management system 900. FIG. 9C shows a rear view of a cable management system 900. FIG. 9D shows a top view of a cable management system 900. FIG. 9E shows a bottom view of a cable management system 900. FIG. 9F shows a right view of a cable management system 900. FIG. 9G shows a left view of a cable management system 900. In certain embodiments, the cable management system 900 corresponds to cable management system 150. In certain embodiments, the cable management system 900 is adaptable to information handling systems having different rear chassis designs. In certain embodiments, the cable management system 900 is adaptable to a plurality of rack depths.

In certain embodiments, the cable management system 900 is configured to be installed to a server rack. In certain embodiments, the cable management system 900 is configured to fit a plurality of different server information handling system chassis designs. In certain embodiments, the plurality of different server information handling system designs includes a rear side structure rear server chassis design. In certain embodiments, the cable management system 900 is configured to fit a plurality of different rack dimensions. In certain embodiments, the plurality of different rack dimensions corresponds to a plurality of EIA rack dimensions.

In certain embodiments, the cable management system 900 includes one or more adjustable mounting components. In certain embodiments, the one or more adjustable mounting components enable the cable management system to fit a plurality of different rack configurations. In certain embodiments, the one or more adjustable mounting components enable the cable management system to fit a plurality of different EIA rack configurations. In certain embodiments, the one or more adjustable mounting components enable a depth of the cable management system 900 to be adjusted.

In certain embodiments, the cable management system 900 includes a first rail mounting component 910, a second rail mounting component 912, a cable management component 914, or a combination thereof. In certain embodiments, the first rail mounting component 910 corresponds to a left side rail mounting component. In certain embodiments, the second rail mounting component 910 corresponds to a right side rail mounting component.

In certain embodiments, the first rail mounting component 910 includes a first rail mounting wall 920, a first cable management component mounting extension 922, or a combination thereof. In certain embodiments, the first rail mounting wall 920 extends substantially perpendicularly to the first cable management component mounting extension 922. In certain embodiments, the first rail mounting wall 920 includes one or more rail mounting features 924. In certain embodiments, the one or more rail mounting features 924 are used to physically attach the first rail mounting component to a rail of a server rack. In certain embodiments, the first cable management component mounting extension 922 defines a plurality of cable management component mounting apertures 926. In certain embodiments, the plurality of cable management component apertures 926 extends horizontally across the first cable management mounting extension 922. In certain embodiments, the first cable management component mounting extension 922 includes a first plurality of guide rails 928.

In certain embodiments, the second rail mounting component 912 includes a second rail mounting wall 930, a second cable management component mounting extension 932, or a combination thereof. In certain embodiments, the second rail mounting wall 930 extends substantially perpendicularly to the second cable management component mounting extension 932. In certain embodiments, the second rail mounting wall 930 includes one or more rail mounting features 934. In certain embodiments, the one or more rail mounting features 934 are used to physically attach the second rail mounting component to a rail of a server rack. In certain embodiments, the second cable management component mounting extension 932 defines a plurality of cable management component mounting apertures 936. In certain embodiments, the plurality of cable management component apertures 936 extends horizontally across the second cable management mounting extension 932. In certain embodiments, the second cable management component mounting extension 932 includes a second plurality of guide rails.

In certain embodiments, the cable management component 914 includes a first mounting extension 940, a second mounting extension 942, a cable management portion 944 or a combination thereof. In certain embodiments, the first mounting extension 940 extends substantially perpendicularly to the cable management portion 944. In certain embodiments, the second mounting extension 942 extends substantially perpendicularly to the cable management portion 944. In certain embodiments, the first mounting extension 940 defines a first mounting extension aperture 946. In certain embodiments, the first mounting extension aperture 946 mates with one of the plurality of cable management component mounting apertures when adjusting the depth of the cable management component 914.

In certain embodiments, the second mounting extension 942 defines a second mounting extension aperture 948. In certain embodiments, the second mounting extension aperture 946 mates with one of the plurality of cable management component mounting apertures when adjusting the depth of the cable management component 914. In certain embodiments, the first mounting extension 940 mates with the first plurality of guide rails 932 of the first cable management component mounting extension 922. In certain embodiments, the first cable management mounting extension 922 slides along the first plurality of guide rails when adjusting the depth of the cable management component 914. In certain embodiments, the second cable management mounting extension 942 mates with the second plurality of guide rails of the second cable management component mounting extension 932. In certain embodiments, the second cable management mounting extension 942 slides along the second plurality of guide rails when adjusting the depth of the cable management component 914.

In certain embodiments, the cable management portion 944 includes a wall 950 and a plurality of cable management features 950 extending from the wall 950. In certain embodiments, the wall 950 defines one or more cable management apertures 954. In certain embodiments, the first mounting extension 940 extends substantially perpendicularly to wall 950 of the cable management portion 944. In certain embodiments, the second mounting extension 942 extends substantially perpendicularly to wall 950 of the cable management portion 944. In certain embodiments, the first mounting extension 940 the second mounting extension 942 and the wall 950 are integrated within a single piece of material.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A cable management system for an information handling system server rack, comprising:
a rail mounting component, the rail mounting component being configured to physically attach to the information handling system server rack; and,
a cable management component, the cable management component being physically attached to the rail mounting component, the cable management component extending across a rear of the information handling system server rack.

2. The cable management system of claim 1, wherein:
a depth of the cable management component is adjustable relative to the information handling system rack.

3. The cable management system of claim 2, wherein:
the rail mounting component includes a rail mounting wall and a cable management component mounting extension, the rail mounting wall extending substantially perpendicularly to the cable management component mounting extension.

4. The cable management system of claim 3, wherein:
the cable management component mounting extension defines a plurality of cable management component apertures.

5. The cable management system of claim 3, wherein:
the cable management component defines a cable management component mounting aperture, the cable management component mounting aperture mating with one of the plurality of cable management component apertures when adjusting the depth of the cable management component.

6. The cable management system of claim 3, wherein:
the cable management component mounting extension includes a plurality of guide rails; and,
the cable management component slides along the plurality of guide rails when adjusting the depth of the cable management component.

7. An information handling system server rack comprising:
a rear side panel; and,
a cable management system, the cable management system comprising
a rail mounting component, the rail mounting component being configured to physically attach to the rear side panel of the information handling system server rack; and,
a cable management component, the cable management component being physically attached to the rail mounting component, the cable management component extending across a rear of the information handling system server rack.

8. The information handling system server rack of claim 7, wherein:
a depth of the cable management component is adjustable relative to the information handling system rack.

9. The information handling system server rack of claim 8, wherein:
the rail mounting component includes a rail mounting wall and a cable management component mounting extension, the rail mounting wall extending substantially perpendicularly to the cable management component mounting extension.

10. The information handling system server rack of claim 9, wherein:
the cable management component mounting extension defines a plurality of cable management component apertures.

11. The information handling system server rack of claim 9, wherein:
the cable management component defines a cable management component mounting aperture, the cable management component mounting aperture mating with one of the plurality of cable management component apertures when adjusting the depth of the cable management component.

12. The information handling system server rack of claim 9, wherein:
the cable management component mounting extension includes a plurality of guide rails; and,
the cable management component slides along the plurality of guide rails when adjusting the depth of the cable management component.
